(19) United States
(12) Patent Application Publication
(10) Pub. No.: US 2026/0238181 A1
(43) Pub. Date: Aug. 13, 2026

(54) SURFACE ACOUSTIC WAVE DEVICE WITH SLIT REFLECTOR

(71) Applicant: Skyworks Solutions, Inc., Irvine, CA (US)

(72) Inventors: Jun Sekimoto, Suita-Shi (JP); Rei Goto, Osaka-Shi (JP)

(21) Appl. No.: 19/379,466

(22) Filed: Nov. 4, 2025

Related U.S. Application Data
(60) Provisional application No. 63/719,358, filed on Nov. 12, 2024.
(60) Provisional application No. 63/719,372, filed on Nov. 12, 2024.

(51) Int. Cl. H03H 9/13; H03H 9/145; H03H 9/17

(52) U.S. Cl. CPC H03H 9/132; H03H 9/14588; H03H 9/17

(57) ABSTRACT

A surface acoustic wave device is disclosed. The surface acoustic wave device includes a multi-layer piezoelectric substrate including a support substrate and a piezoelectric layer, an interdigital transducer electrode in electrical communication with the piezoelectric layer, and a slit positioned in a wave propagation direction of the interdigital transducer electrode. The slit can have a depth extending at least partially through a thickness of the multi-layer piezoelectric substrate.

### INCORPORATION BY REFERENCE TO ANY PRIORITY APPLICATIONS

Any and all applications for which a foreign or domestic priority claim is identified in the Application Data Sheet as filed with the present application, including U.S. Provisional Patent Application No. 63/719,358, filed on Nov. 12, 2024, titled “SURFACE ACOUSTIC WAVE DEVICE WITH SLIT REFLECTOR,” and U.S. Provisional Patent Application No. 63/719,372, filed on Nov. 12, 2024, titled “SURFACE ACOUSTIC WAVE DEVICE WITH REFLECTOR HAVING SLIT AND GRATING REFLECTOR,” are hereby incorporated by reference under 37 CFR 1.57 in their entirety herein.

### BACKGROUND

### Field The disclosed technology relates to acoustic wave devices. Embodiments of this disclosure relate to surface acoustic wave devices with a slit reflector.

### Description of Related Technology

Acoustic wave filters can be implemented in radio frequency electronic systems. For instance, filters in a radio frequency front end of a mobile phone can include acoustic wave filters. An acoustic wave filter can filter a radio frequency signal. An acoustic wave filter can be a band-pass filter. A plurality of acoustic wave filters can be arranged as a multiplexer. For example, two acoustic wave filters can be arranged as a duplexer.

An acoustic wave filter can include a plurality of resonators arranged to filter a radio frequency signal. Example acoustic wave filters include surface acoustic wave (SAW) filters and bulk acoustic wave (BAW) filters. A SAW resonator can include an interdigital transducer electrode on a piezoelectric substrate. The surface acoustic wave resonator can generate a surface acoustic wave on a surface of the piezoelectric layer on which the interdigital transducer electrode is disposed. A multilayer piezoelectric substrate surface acoustic wave (MPS-SAW) resonator is an example of the SAW resonator.

### SUMMARY

The innovations described in the claims each have several aspects, no single one of which is solely responsible for its desirable attributes. Without limiting the scope of the claims, some prominent features of this disclosure will now be briefly described.

In some aspects, the techniques described herein relate to a surface acoustic wave device including: a multi-layer piezoelectric substrate including a support substrate and a piezoelectric layer; an interdigital transducer electrode in electrical communication with the piezoelectric layer; and a slit positioned in a wave propagation direction of the interdigital transducer electrode, the slit having a depth extending at least partially through a thickness of the multi-layer piezoelectric substrate.

In some embodiments, the techniques described herein relate to a surface acoustic wave device wherein the depth of the slit is at least 1 L where L is a wavelength of a wave generated by the surface acoustic wave device.

In some embodiments, the techniques described herein relate to a surface acoustic wave device wherein the depth of the slit is in a range between 0.25 L and 1.5 L where L is a wavelength of a wave generated by the surface acoustic wave device.

In some embodiments, the techniques described herein relate to a surface acoustic wave device wherein the multi-layer piezoelectric substrate further includes an intermediate layer between the support substrate and the piezoelectric layer.

In some embodiments, the techniques described herein relate to a surface acoustic wave device wherein the depth of the slit extends through an entire thickness of the piezoelectric layer.

In some embodiments, the techniques described herein relate to a surface acoustic wave device wherein the depth of the slit extends through an entire thickness of the intermediate layer.

In some embodiments, the techniques described herein relate to a surface acoustic wave device wherein the multi-layer piezoelectric substrate further includes a trap-rich layer between the intermediate layer and the support substrate.

In some embodiments, the techniques described herein relate to a surface acoustic wave device wherein the depth of the slit extends through an entire thickness of the piezoelectric layer and partially through a thickness of the support substrate.

In some embodiments, the techniques described herein relate to a surface acoustic wave device wherein a gap between the slit and the interdigital transducer electrode is in a range between 0 and 2 L where L is a wavelength of a wave generated by the surface acoustic wave device.

In some embodiments, the techniques described herein relate to a surface acoustic wave device wherein a gap between the slit and the interdigital transducer electrode is in a range between 0.75 L and 1.25 L.

In some embodiments, the techniques described herein relate to a surface acoustic wave device further including a second slit, wherein the interdigital transducer electrode is positioned between the slit and the second slit.

In some embodiments, the techniques described herein relate to a surface acoustic wave device wherein a length of the slit is greater than a length of a finger of the interdigital transducer electrode.

In some aspects, the techniques described herein relate to a surface acoustic wave device wherein the interdigital transducer electrode is positioned at or near an edge of the multi-layer piezoelectric substrate, the interdigital transducer electrode positioned between the edge and the slit such that the edge of the multi-layer piezoelectric substrate and the slit function as a pair of reflectors.

In some aspects, the techniques described herein relate to a surface acoustic wave device wherein the interdigital transducer electrode includes a plurality of fingers including a first edge finger, a second edge finger, and center fingers between the first edge finger and the second edge finger, the first edge finger is closest to the slit among the plurality of fingers and has a width greater than a width of the center fingers.

In some embodiments, the techniques described herein relate to a surface acoustic wave device wherein the second edge finger has a width greater than the width of the center fingers.

In some embodiments, the techniques described herein relate to a surface acoustic wave device wherein the width of the first edge finger is in a range between 1.5 to 3 times the width of the center fingers.

In some aspects, the techniques described herein relate to a surface acoustic wave device including: a piezoelectric layer; an interdigital transducer electrode in electrical communication with the piezoelectric layer; and a pair of slits including a first slit and a second slit positioned in a wave propagation direction of the interdigital transducer electrode, the interdigital transducer electrode is positioned between the pair of slits, the slit having a depth extending at least partially through a thickness of the piezoelectric layer.

In some embodiments, the techniques described herein relate to a surface acoustic wave device wherein the depth of the slit is at least 1 L where L is a wavelength of a wave generated by the surface acoustic wave device.

In some embodiments, the techniques described herein relate to a surface acoustic wave device wherein a gap between the slit and the interdigital transducer electrode is in a range between 0.5 L and 2 L.

In some aspects, the techniques described herein relate to a surface acoustic wave device wherein the interdigital transducer electrode includes a plurality of fingers including a first edge finger, a second edge finger, and center fingers between the first edge finger and the second edge finger, the first edge finger is closest to the first slit among the plurality of fingers and has a width greater than a width of the center fingers.

In some embodiments, the techniques described herein relate to a surface acoustic wave device wherein the second edge finger is positioned closest to the second slit among the plurality of fingers and has a width greater than the width of the center fingers.

In some aspects, the techniques described herein relate to a surface acoustic wave device including: a multi-layer piezoelectric substrate including a support substrate and a piezoelectric layer; an interdigital transducer electrode in electrical communication with the piezoelectric layer; and a slit positioned in a wave propagation direction of the interdigital transducer electrode, the slit extending at least 0.25 L into the multi-layer piezoelectric substrate, L being a wavelength of a wave generated by the surface acoustic wave device.

In some embodiments, the techniques described herein relate to a surface acoustic wave device wherein the slit extends at least 1 L into the multi-layer piezoelectric substrate.

In some embodiments, the techniques described herein relate to a surface acoustic wave device wherein the slit extends into the multi-layer piezoelectric substrate in a range between 0.25 L and 1.5 L.

In some embodiments, the techniques described herein relate to a surface acoustic wave device wherein a gap between the slit and the interdigital transducer electrode is in a range between 0.5 L and 2 L.

In some aspects, the techniques described herein relate to a surface acoustic wave device including: a multi-layer piezoelectric substrate including a support substrate and a piezoelectric layer; an interdigital transducer electrode in electrical communication with the piezoelectric layer; and a reflector positioned in a wave propagation direction of the interdigital transducer electrode, the reflector including a slit and a grating reflector, the slit extends at least partially through a thickness of the multi-layer piezoelectric substrate.

In some embodiments, the techniques described herein relate to a surface acoustic wave device wherein the grating reflector is positioned between the interdigital transducer electrode and the slit.

In some embodiments, the techniques described herein relate to a surface acoustic wave device wherein the slit extends at least 0.25 L into the multi-layer piezoelectric substrate, where L is a wavelength of a wave generated by the surface acoustic wave device.

In some embodiments, the techniques described herein relate to a surface acoustic wave device wherein the slit extends into the multi-layer piezoelectric substrate in a range between 0.25 L and 1.5 L.

In some embodiments, the techniques described herein relate to a surface acoustic wave device wherein the multi-layer piezoelectric substrate further includes an intermediate layer between the support substrate and the piezoelectric layer.

In some embodiments, the techniques described herein relate to a surface acoustic wave device wherein the slit extends through an entire thickness of the piezoelectric layer.

In some embodiments, the techniques described herein relate to a surface acoustic wave device wherein the slit extends through an entire thickness of the intermediate layer.

In some embodiments, the techniques described herein relate to a surface acoustic wave device wherein the multi-layer piezoelectric substrate further includes a trap-rich layer between the intermediate layer and the support substrate.

In some embodiments, the techniques described herein relate to a surface acoustic wave device wherein the slit extends through an entire thickness of the piezoelectric layer and partially through a thickness of the support substrate.

In some embodiments, the techniques described herein relate to a surface acoustic wave device wherein a gap between the slit and the grating reflector is in a range between 0.5 L and 2 L where L is a wavelength of a wave generated by the surface acoustic wave device.

In some embodiments, the techniques described herein relate to a surface acoustic wave device wherein a gap between the slit and the grating reflector is in a range between 0.75 L and 1.25 L.

In some embodiments, the techniques described herein relate to a surface acoustic wave device further including a second slit, wherein the interdigital transducer electrode is positioned between the slit and the second slit.

In some embodiments, the techniques described herein relate to a surface acoustic wave device wherein a length of the slit is greater than a length of a finger of the interdigital transducer electrode.

In some aspects, the techniques described herein relate to a surface acoustic wave device wherein the interdigital transducer electrode is positioned at or near an edge of the multi-layer piezoelectric substrate, the interdigital transducer electrode positioned between the edge and the slit such that the edge of the multi-layer piezoelectric substrate and the slit function as a pair of reflectors.

In some embodiments, the techniques described herein relate to a surface acoustic wave device wherein the grating reflector is a grating metal reflector.

In some embodiments, the techniques described herein relate to a surface acoustic wave device wherein a material of the grating reflector includes a material of the interdigital transducer electrode.

In some embodiments, the techniques described herein relate to a surface acoustic wave device wherein a number of fingers in the grating reflector is less than 10% of a number of fingers in the interdigital transducer electrode.

In some embodiments, the techniques described herein relate to a surface acoustic wave device including: a piezoelectric layer; an interdigital transducer electrode in electrical communication with the piezoelectric layer; a slit reflector positioned in a wave propagation direction of the interdigital transducer electrode; and a grating reflector between the interdigital transducer electrode and the slit reflector.

In some embodiments, the techniques described herein relate to a surface acoustic wave device further including a second slit reflector and a second grating reflector, wherein the interdigital transducer electrode is positioned between the grating reflector and the second grating reflector, and the second grating reflector is positioned between the interdigital transducer electrode and the second slit reflector.

In some aspects, the techniques described herein relate to an acoustic wave filter for filtering a radio frequency signal, the acoustic wave filter including: a surface acoustic wave device of any preceding claim; and a plurality of additional acoustic wave resonators, the surface acoustic wave device and the plurality of additional acoustic wave resonators configured to filter the radio frequency signal.

### BRIEF DESCRIPTION OF THE DRAWINGS

Embodiments of this disclosure will now be described, by way of non-limiting example, with reference to the accompanying drawings.

FIG. 1A is a schematic top plan view of a surface acoustic wave (SAW) device according to an embodiment.

FIG. 1B is a schematic cross-sectional side view of the SAW device of FIG. 1A.

FIGS. 2A-2D are schematic cross-sectional side views of the SAW device according to various embodiments.

FIGS. 3A-3C are graphs showing simulation results of the performance of a conventional SAW device having a grating metal reflector, a SAW resonator without a reflector, and the SAW device of FIGS. 1A and 1B.

FIGS. 4A-4C are graphs showing simulation results of the performance of the SAW device with different slit depths (at d=250 nm, 500 nm, 750 nm, 1000 nm, 2000 nm, and 3000 nm).

FIGS. 5A-5C are graphs showing simulation results of the performance of the SAW device 1 with different slit gaps (at g1=1 μm, 2 μm, and 4 μm).

FIGS. 5D-5F are graphs showing simulation results of the performance of a conventional SAW device having a grating metal reflector, the SAW device of FIGS. 1A-1B, and the SAW device of FIGS. 1A-1B with the wider edge-finger structure.

FIGS. 5G-5L are graphs showing simulation results of the performance of the SAW device of FIG. 1A, and the SAW device of FIG. 1A with the wider edge-finger structure.

FIG. 6A is a schematic top plan view of a SAW device according to an embodiment.

FIG. 6B is a schematic cross-sectional side view of the SAW device of FIG. 6A.

FIGS. 7A-7C are graphs showing simulation results of the performance of the SAW device with different slit depths (at d=250 nm, 500 nm, 750 nm, 1000 nm, 2000 nm, and 3000 nm).

FIGS. 8A-8C are graphs showing simulation results of the performance of the SAW device 2 with different slit gaps (at g2=1 μm, 2 μm, and 4 μm).

FIG. 9A is a schematic top plan view of a SAW device according to an embodiment.

FIGS. 9B-9D are graphs showing simulation results of the performance of the SAW device of FIG. 1A with the wider edge-finger structure and the SAW device of FIG. 9A.

FIG. 10A is a schematic diagram of a transmit filter that includes a surface acoustic wave resonator according to an embodiment.

FIG. 10B is a schematic diagram of a receive filter that includes a surface acoustic wave resonator according to an embodiment.

FIG. 11 is a schematic diagram of a radio frequency module that includes a surface acoustic wave resonator according to an embodiment.

FIG. 12 is a schematic diagram of a radio frequency module that includes filters with surface acoustic wave resonators according to an embodiment.

FIG. 13 is a schematic block diagram of a module that includes an antenna switch and duplexers that include a surface acoustic wave resonator according to an embodiment.

FIG. 14A is a schematic block diagram of a module that includes a power amplifier, a radio frequency switch, and duplexers that include a surface acoustic wave resonator according to an embodiment.

FIG. 14B is a schematic block diagram of a module that includes filters, a radio frequency switch, and a low noise amplifier according to an embodiment.

FIG. 15A is a schematic block diagram of a wireless communication device that includes a filter with a surface acoustic wave resonator in accordance with one or more embodiments.

FIG. 15B is a schematic block diagram of another wireless communication device that includes a filter with a surface acoustic wave resonator in accordance with one or more embodiments.

### DETAILED DESCRIPTION

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

Acoustic wave filters can filter radio frequency (RF) signals in a variety of applications, such as in an RF front end of a mobile phone. An acoustic wave filter can be implemented with surface acoustic wave (SAW) devices, such as shear horizontal mode surface acoustic wave (SH-SAW) devices and Rayleigh mode SAW devices. Certain SAW devices may be referred to as SAW resonators. Any features of the SAW resonators discussed herein can be implemented in any suitable SAW device such as a multilayer piezoelectric substrate surface acoustic wave (MPS-SAW) device.

In general, high quality factor (Q), large effective electromechanical coupling coefficient (k2), high frequency ability, and spurious free response can be significant aspects for acoustic wave elements to enable low-loss filters, delay lines, stable oscillators, and sensitive sensors. Also, device size reduction can be important for module floor planning and cost reduction. It can be challenging to maintain the device performance while reducing the device size.

In a SAW filter, a reflector can reflect acoustic waves back into the active region of the acoustic wave device, enhancing the filter's performance by confining the wave energy. A grating reflector includes a series of periodically spaced metal fingers that act as acoustic mirrors. These fingers can create an impedance mismatch that reflects surface acoustic waves, enabling the formation of standing wave patterns for effective filtering. The grating reflector's periodicity can be designed to match the wavelength of the desired wave, optimizing reflection and resonance. However, grating reflectors can take up significant real estate on the SAW device, as they span a certain length to efficiently reflect the waves. This spatial constraint can limit the device's overall compactness, particularly in miniaturized designs, where balancing performance and footprint is significant.

Embodiments disclosed herein relate to SAW devices (e.g., multi-layer piezoelectric substrate surface acoustic wave (MPS-SAW) devices) with a reflector that includes a slit. The reflector can be referred to as a slit reflector. A SAW device according to various embodiments can include a piezoelectric layer, an interdigital transducer electrode that is in electrical communication with the piezoelectric layer, and a slit positioned in a wave propagation direction of the interdigital transducer electrode. The SAW device can include a multi-layer piezoelectric substrate including a support substrate and the piezoelectric layer. The slit can have a depth that extends at least partially through (e.g., entirely through) a thickness of the multi-layer piezoelectric substrate. A width of the slit can be significantly smaller than a grating reflector. Therefore, the slit reflector can reduce the lateral size of the SAW device as compared to the grating reflector. In some embodiments, the SAW device can include the slit and a grating reflector.

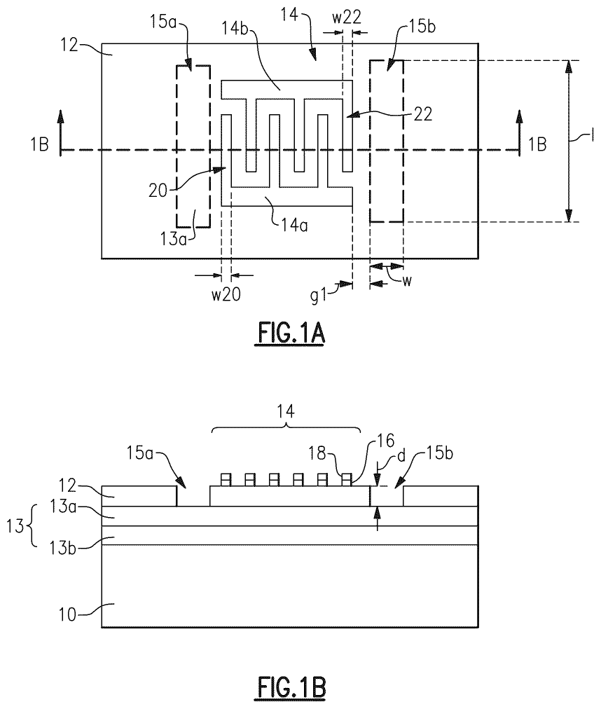

FIG. 1A is a schematic top plan view of a surface acoustic wave (SAW) device 1 according to an embodiment. FIG. 1B is a schematic cross-sectional side view of the SAW device 1 of FIG. 1A. The SAW device 1 is an example of a multilayer piezoelectric substrate surface acoustic wave (MPS-SAW) device. The SAW device 1 can include a multi-layer piezoelectric substrate (MPS) that includes a support substrate 10, a piezoelectric layer 12, and an intermediate structure 13 between the support substrate 10 and the piezoelectric layer 12. The support substrate 10 and the intermediate structure 13 can be part of a support structure of the MPS. The SAW device 1 can include an interdigital transducer (IDT) electrode 14 in electrical communication with the piezoelectric layer 12, and a pair of slits 15a, 15b positioned in a wave propagation direction of the IDT electrode 14.

The support substrate 10 can be any suitable substrate layer, such as a silicon layer, a quartz layer, a ceramic layer, a glass layer, a spinel layer, a magnesium oxide spinel layer, a sapphire layer, a diamond layer, a silicon carbide layer, a silicon nitride layer, an aluminum nitride layer, or the like. The support substrate 10 can have a relatively high impedance. An acoustic impedance of the support substrate 10 can be higher than an acoustic impedance of the piezoelectric layer 12. For instance, the support substrate 10 can have a higher acoustic impedance than an acoustic impedance of lithium niobate and a higher acoustic impedance than lithium tantalate.

The piezoelectric layer 12 can include any suitable piezoelectric layer, such as a lithium based piezoelectric layer. In some embodiments, the piezoelectric layer 12 can be a lithium tantalate (LT) layer. For example, the piezoelectric layer 12 can be an LT layer having a cut angle of 20° (20 ° Y-cut X-propagation LT) or a cut angle of 60° (60 ° Y-cut X-propagation LT). For example, the piezoelectric layer 12 can be 20±10° Y-cut LT, 42+25° Y-cut LT, 42±20° Y-cut LT, 42±15° Y-cut LT, 42±10° Y-cut LT, 42+5° Y-cut LT, 60±20° Y-cut LT, 60±15° Y-cut LT, 60±10° Y-cut LT, or 60±5° Y-cut LT. Any other suitable piezoelectric material, such as a lithium niobate (LN) layer, can be used as the piezoelectric layer 12. For example, the piezoelectric layer 12 can be an LN layer having a cut angle of about 118° (118 ° Y-cut X-propagation LN) or more or a cut angle of about 132° (132 ° Y-cut X-propagation LN) or less. For example, the piezoelectric layer 12 can be 125±20° Y-cut LN, 125±15° Y-cut LN, 125±10° Y-cut LN, or 125±5° Y-cut LN. A thickness of the piezoelectric layer 12 can be selected based on a wavelength 2 or L of a surface acoustic wave generated by the SAW device 1 in certain applications. In some embodiments, the wavelength L can be in a range between, for example, 3 micrometers and 6 micrometers, 3.5 micrometers and 6 micrometers, 3 micrometers and 5.5 micrometers, or 3.5 micrometers and 5.5 micrometers. The piezoelectric layer 12 can be sufficiently thick to avoid significant frequency variation. For example, the thickness of the piezoelectric layer 12 can be in a range of 0.1 L to 0.5 , 0.1 L to 0.3 L, or 0.1 L to 0.2 L. Selecting the thickness of the piezoelectric layer 12 from these ranges can be critical in avoiding significant frequency variation and providing sufficient temperature coefficient of frequency for the SAW device 1. In some embodiments, the piezoelectric layer 12 can include lithium tantalate (LT) and lithium niobate (LN).

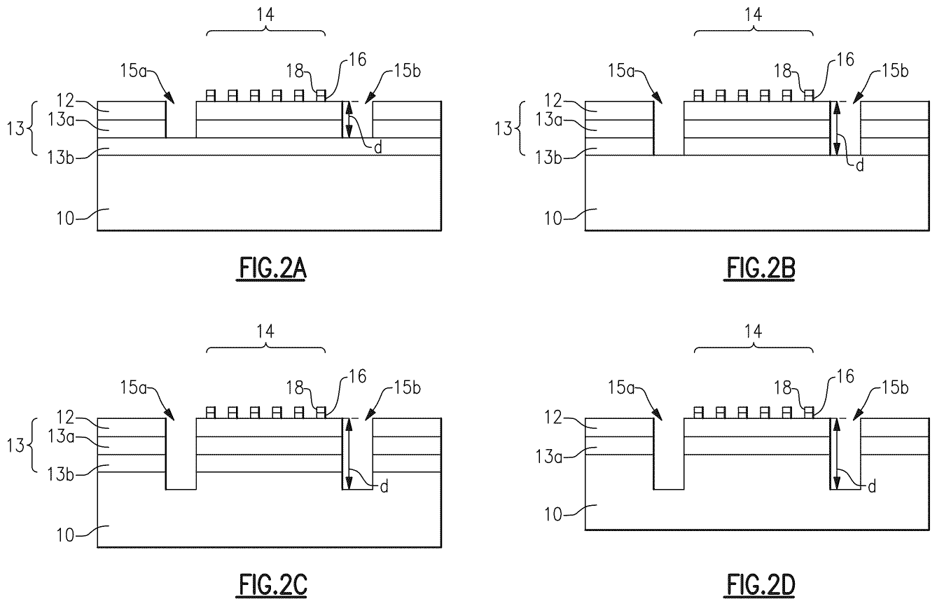

The intermediate structure 13 can include a functional layer 13a and a trap-rich layer 13b. In some embodiments, the functional layer 13a can act as an adhesive layer. The functional layer 13a can include any suitable material. The functional layer 13a can be, for example, an oxide layer (e.g., a silicon dioxide (SiO₂) layer) or a silicon oxynitride layer. The functional layer 13a can enhance energy confinement and TCF tunability. The trap-rich layer 13b can mitigate formation of the parasitic surface conduction at or near a surface of the support substrate 10 that faces the intermediate structure 13. The trap-rich layer 13b can improve the electrical characteristics of the SAW device 1 by increasing the depth and sharpness on the anti-resonance peak. The trap-rich layer 13b may be omitted in some embodiments (see FIG. 2D).

The illustrated IDT electrode 14 can include a first layer 16 and a second layer 18. In the SAW device 1, the IDT electrode 14 includes separate IDT layers (e.g., the first layer 16 and the second layer 18) that impact acoustic properties and electrical properties. Accordingly, in some embodiments, electrical properties, such as insertion loss, can be improved by adjusting one of the IDT layers without significantly impacting acoustic properties.

The IDT electrode 14 can include a first electrode element 14a including a first bus bar and first set of fingers extending from the first bus bar and a second electrode element 14b including a second bus bar and second set of fingers extending from the second bus bar. In some embodiments, the first electrode element 14a or the second electrode element 14b can be coupled to a signal line, and the other one of the first electrode element 14a or the second electrode element 14b can be coupled to ground (GND).

The IDT electrode 14 can include any suitable number of fingers that extend from respective bus bars. The number of fingers can affect the resonance characteristics of the SAW device 1. The number of fingers can be selected based at least in part on the desired resonance frequency, bandwidth, and insertion loss, while taking into account the acoustic wavelength determined by the electrode pitch and acoustic velocity. When the number of fingers is increased, the acoustic energy conversion efficiency and reflectivity generally improve, resulting in a higher Q factor, narrower bandwidth, and reduced insertion loss. The number of fingers can be determined by balancing trade-offs between frequency selectivity, impedance characteristics, device size, and manufacturing considerations in view of the intended application and desired performance of the SAW device 1.

The fingers can include a first edge finger 20 having a width w20, a second edge finger 22 having a width w22, and center fingers between the first edge finger 20 and the second edge finger 22. The first edge finger 20 can be part of the first electrode element 14a and a finger of the IDT electrode 14 that is closest to the slit 15a. The second edge finger 22 can be part of the second electrode element 14b and a finger of the IDT electrode 14 that is closest to the slit 15b.

The first layer 16 of the IDT electrode 14 can be referred to as a lower electrode layer. The first layer 16 of the IDT electrode 14 is disposed between the second layer 18 of the IDT electrode 14 and the piezoelectric layer 12. As illustrated, the first layer 16 of the IDT electrode 14 can have a first side in physical contact with the piezoelectric layer 12 and a second side in physical contact with the second layer 18 of the IDT electrode 14. The second layer 18 of the IDT electrode 14 can be referred to as an upper electrode layer. The second layer 18 of the IDT electrode 14 can be disposed over the first layer 16 of the IDT electrode 14. As illustrated, the second layer 18 of the IDT electrode 14 can have a first side in physical contact with the first layer 16 of the IDT electrode 14. In some other embodiments, the first layer 16 and the second layer 18 can be switched.

The IDT electrode 14 can include any suitable material. For example, the first layer 16 can be tungsten (W) and the second layer 18 can be aluminum (Al) in certain embodiments. The IDT electrode 14 may include one or more other metals, such as copper (Cu), magnesium (Mg), titanium (Ti), molybdenum (Mo), etc. The IDT electrode 14 may include alloys, such as AlMgCu, AlCu, etc. In some embodiments, a thickness of the first layer 16 can be in a range from 0.01 L to 0.075 L and a thickness of the second layer 18 can be in a range from 0.05 L to 0.2 L. For example, when the wavelength L is 4 μm, the thickness of the first layer 16 can be about 40 nm to 300 nm and the thickness of the second layer 18 can be about 200 nm to 800 nm. Although the IDT electrode 14 has a dual-layer structure in the illustrated embodiments, any suitable principles and advantages disclosed herein can be applied to single layer IDT electrodes or multi-layer IDT electrodes that include three or more IDT layers. The IDT electrode 14 can be formed with (e.g., formed on or at least partially in) the piezoelectric layer 12. The piezoelectric layer 12 and the IDT electrode 14 can be provided in any suitable manner. For example, the piezoelectric layer 12 and the IDT electrode 14 can be provided in sequence. When the interdigital transducer electrode is provided at least partially in the piezoelectric layer 12, the piezoelectric layer 12 can be partially etched and/or provided in a plurality of steps.

The surface acoustic wave generated by the IDT electrode 14 can propagate in a wave propagation direction that is generally perpendicular to the length direction of the fingers of the IDT electrode 14. The IDT electrode 14 is positioned laterally between the pair of slits 15a, 15b in the wave propagation direction. The slits 15a, 15b can act as acoustic mirrors and be referred to as slit reflectors. The slit 15a and the slit 15b can have the same or generally similar dimensions, in some embodiments. In some other embodiments, the slit 15a and the slit 15b may have different dimensions. When the IDT electrode is positioned at or near (e.g., within 10 μm from) an edge of the MPS, the one of the slits 15a, 15b may be omitted and the edge of the MPS may function as a reflector. The slits 15a, 15b can be formed in any suitable manner. For example, the slits 15a, 15b can be formed by way of etching. In some embodiments, a sidewall of the slit 15a, 15b may have a tapered sidewall indicative of the etching process. For example, the slits 15a, 15b may have a narrower width towards the bottom of the slits 15a, 15b and a wider width at or near the top of the slits 15a, 15b. The slits 15a, 15b can be formed after forming the IDT electrode 14.

The slit 15a, 15b has a depth d, a width w1, and a length l. The slits 15a, 15b of the SAW device 1 can have any suitable depth d, width w1, and length l. In some embodiments, the depth d can be in a range between 250 nm and 4000 nm, 1000 nm and 4000 nm, 1500 nm and 4000 nm, 2000 nm and 4000 nm, 3000 nm and 4000 nm, 1000 nm and 3000 nm, 1500 nm and 3500 nm, or 2000 nm and 3500 nm. In some embodiments, the depth d can be in a range between 0.25 L and 1.5 L, 0.25 L and 1.25 L, 0.5 L and 2 L, 1 L and 2 L, 0.5 L and 1.5 L, or 0.8 L and 2 L, where the wavelength L of the surface acoustic wave generated by the SAW device 1 can be in a range between, for example, 3 micrometers and 6 micrometers, 3.5 micrometers and 6 micrometers, 3 micrometers and 5.5 micrometers, or 3.5 micrometers and 5.5 micrometers. In FIGS. 1A and 1B, the depth d of the slits 15a, 15b are shown to be the same as the thickness of the piezoelectric layer 12. However, depending on the depth of the slits 15a, 15b, the slits 15a, 15b may extend, for example, (1) partially through the piezoelectric layer 12, (2) completely through the piezoelectric layer 12, (3) completely through the piezoelectric layer 12 and partially through the functional layer 13a, (4) completely through the piezoelectric layer 12 and the functional layer 13a (see FIG. 2A), (5) completely through the piezoelectric layer 12 and the functional layer 13a, and partially through the trap-rich layer 13b, (6) completely through the piezoelectric layer 12 (see FIG. 2B), the functional layer 13a, and the trap-rich layer 13b, or (7) completely through the piezoelectric layer 12, the functional layer 13a, and the trap-rich layer 13b, and partially through the support substrate 10 (see FIG. 2C).

In some embodiments, the width w1 can be as small as the manufacturing process permits. For example, the width w1 can be in a range between 1 μm and 8 μm, 2 μm and 8 μm, 3 μm and 7 μm, or 3.5 μm and 4.5 μm. In some embodiments, the length 1 of the slit 15a, 15b can be selected based on the length of the active region of the IDT electrode 14. For example, the length 1 of the slit 15a, 15b can be greater than the length of the active region of the IDT electrode 14 or greater than a distance between a pair of bus bars of the IDT electrode 14. The length 1 of the slit 15a, 15b can be greater than a length of a finger of the IDT electrode 14. The slit 15a, 15b and the IDT electrode 14 can be spaced apart by a gap g1. The gap g1 can be in a range between, for example, 0 and 10 μm, 1 μm and 10 μm, 2 μm and 10 μm, 1 μm and 5 μm, or 3 μm and 4 μm. In some embodiments, the gap g1 can be in a range between 0 and 2 L, 0.5 L and 2 L, 0.75 L and 1.25 L, 1 L and 2 L, or 0.5 L and 1.5 L. When the gap g1 is 0 (no gap between the IDT electrode 14 and the slits 15a, 15b), an edge of the IDT electrode (e.g., an edge of the first edge finger 20 or the second edge finger 22) can align with the slit 15a, 15b.

In some embodiments, the fingers of the IDT electrode 14 can have a width in a range between 0.11 L and 0.31 L, or 0.16 L and 0.26 L. In some embodiments, the fingers of the IDT electrode 14 can have a width in a range between 0.85 μm and 1 μm, or 0.9 μm and 0.95 μm. In some embodiments, the width w20 of the first edge finger 20 and the width w22 of the second edge finger 22 can be greater than the widths of the other fingers. Such structures of the SAW device 1 having the greater width(s) for the first edge finger 20 and/or the second edge finger 22 can be referred to as a wider edge-finger structure. Unless otherwise the wider edge-finger structure is called out, it can be assumed in this disclosure that the finger width of the fingers in the IDT electrode 14 are generally the same. However, a skilled artisan will understand that implementation of the wider edge-finger structure can be feasible in any embodiments disclosed herein. In some applications, having a greater width for the width w20 and/or the width w22 can contribute to longitudinal mode suppression. The width w20 and/or the width w22 can be in a range of, for example, 1.5 to 10, 1.5 to 3, or 2 to 10 times the width of the center fingers located between the first edge finger 20 and the second edge finger 22. In some embodiments, the width w20 and/or the width w22 may be greater than 10 times the width of the center fingers. The width w20 and/or the width w22 can be in a range of, for example, 1.275 μm to 3 μm, 2 μm to 3 μm, or 2.2 μm to 2.7 μm. When the width w20 or the width w22 is wider, the SAW device 1 can be more robust and may provide more process variations as compared to a narrower width. There can be a cycle of sweet spots for optimal width differences between the width w20 and/or the width w22 and the width of the center fingers.

In some embodiments, one or more piston mode structures may be implemented with the IDT electrode 14 in any suitable manner. The one or more piston mode structures can effectively suppress the transverse mode associated with the SAW device 1.

FIGS. 2A-2D are schematic cross-sectional side views of the SAW device 1 according to various embodiments. Unless otherwise noted, the components shown in FIGS. 2A-2D may be structurally and/or functionally the same as or generally similar to like components disclosed herein.

In FIG. 2A, the depth d of the slits 15a, 15b can extend completely through the piezoelectric layer 12 and the functional layer 13a. In FIG. 2B, the depth d of the slits 15a, 15b can extend completely through the piezoelectric layer 12. In FIG. 2C, the depth d of the slits 15a, 15b can extend completely through the piezoelectric layer 12, the functional layer 13a, and the trap-rich layer 13b, and partially through the support substrate 10. In FIG. 2D, the trap-rich layer 13b is omitted. In FIG. 2D, the depthd of the slits 15a, 15b can extend completely through the piezoelectric layer 12 and the functional layer 13a, and partially through the support substrate 10. As described above, the slits 15a, 15b can have any suitable depth d, width w1, and length l. Also, the layers of the MPS disclosed herein may have any suitable thicknesses.

A SAW device that includes a grating reflector may have a reflector lateral dimension in the wave propagation direction in a range between, for example, 50 μm and 600 μm. Therefore, the slit reflectors (e.g., the slits 15a, 15b) disclosed herein can significantly reduce the lateral dimension of the reflector. The slits 15a, 15b disclosed herein can significantly reduce the lateral dimension of the reflector with an improved performance or without significantly degrading the acoustic performance.

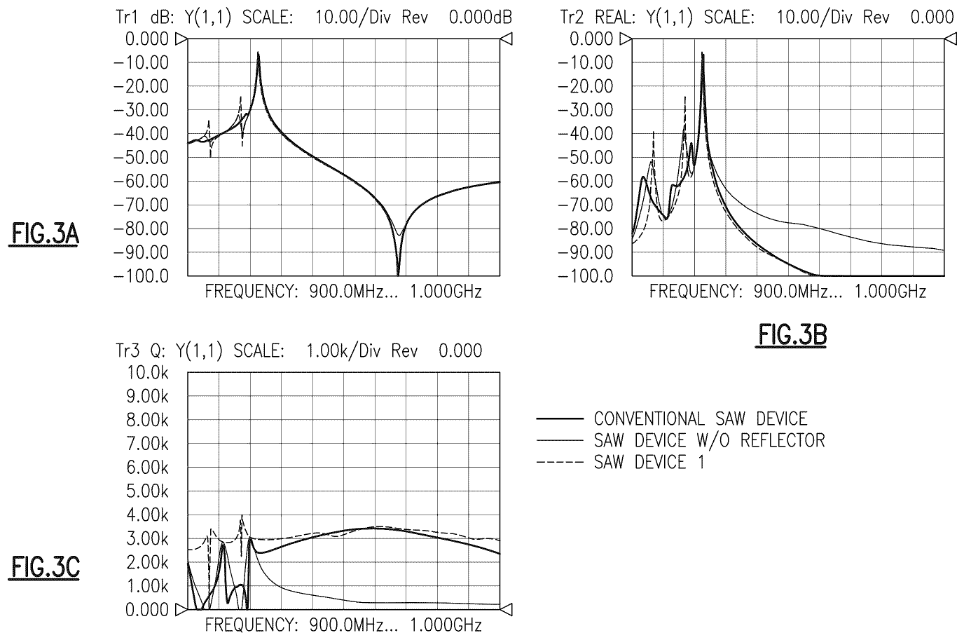

FIGS. 3A-3C are graphs showing simulation results of the performance of a conventional SAW device having a grating metal reflector, a SAW resonator without a reflector, and the SAW device 1. In the simulations, the wavelength L is set to 4 μm and the duty factor is set to 0.46. The simulation results indicate that the slits 15a, 15b can sufficiently confine acoustic energy in the SAW device 1, and provide an improved quality factor Q. The effect of the slits 15a, 15b can be changed by, for example, adjusting the dimensions of the slits 15a, 15b.

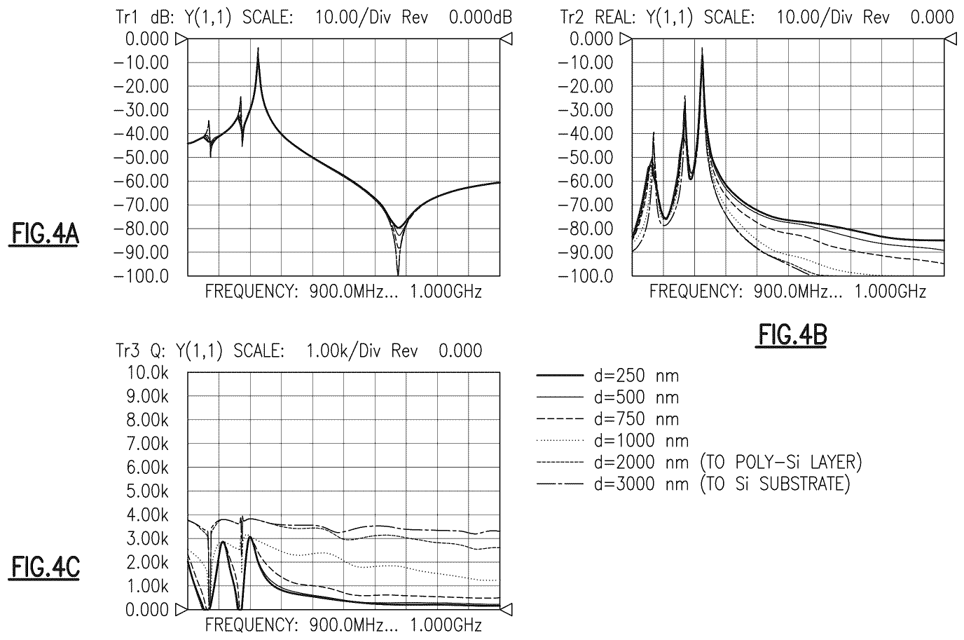

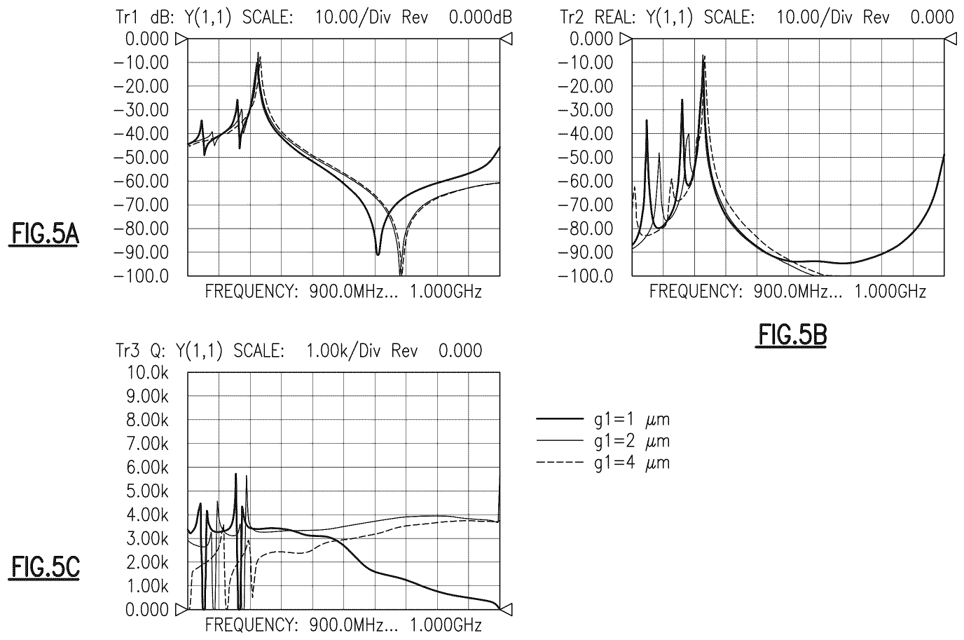

FIGS. 4A-4C are graphs showing simulation results of the performance of the SAW device 1 with different depths d (at d=250 nm, 500 nm, 750 nm, 1000 nm, 2000 nm, and 3000 nm) of the slits 15a, 15b. In the simulations, a 1000 nm silicon substrate is used as the support substrate 10, a 1000 nm thick lithium tantalate layer is used as the piezoelectric layer 12, a 1000 nm thick silicon dioxide (SiO2) layer is used as the functional layer 13a, and a 1000 nm polycrystalline silicon layer is used as the trap-rich layer 13b. The simulation results of FIGS. 4A-4C indicate that the slits 15a, 15b can provide sufficient reflector function when the depth d is greater than 1000 nm, greater than 2000 nm or greater than 3000 nm, and can provide more effective reflector function when the depth is greater.

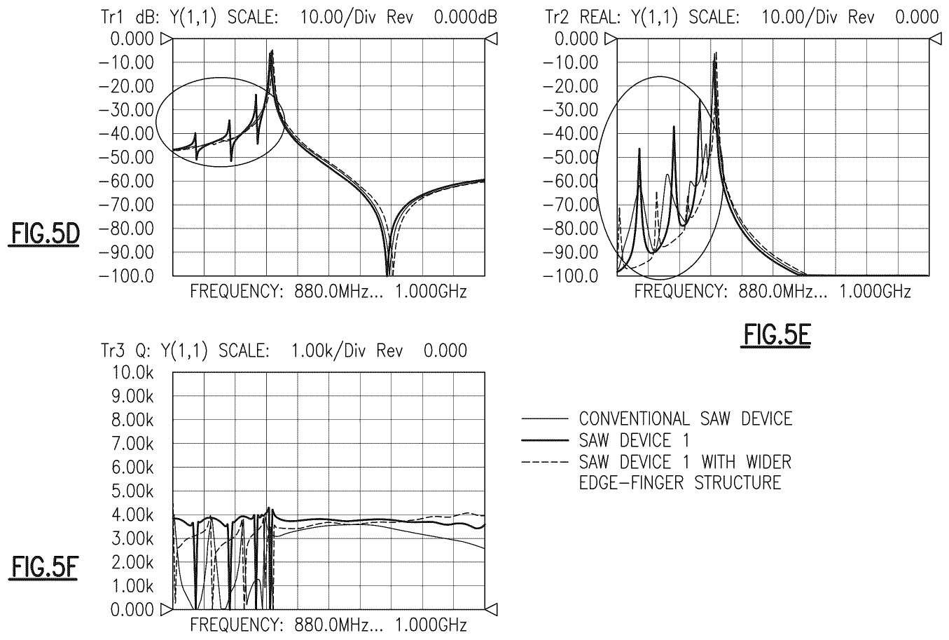

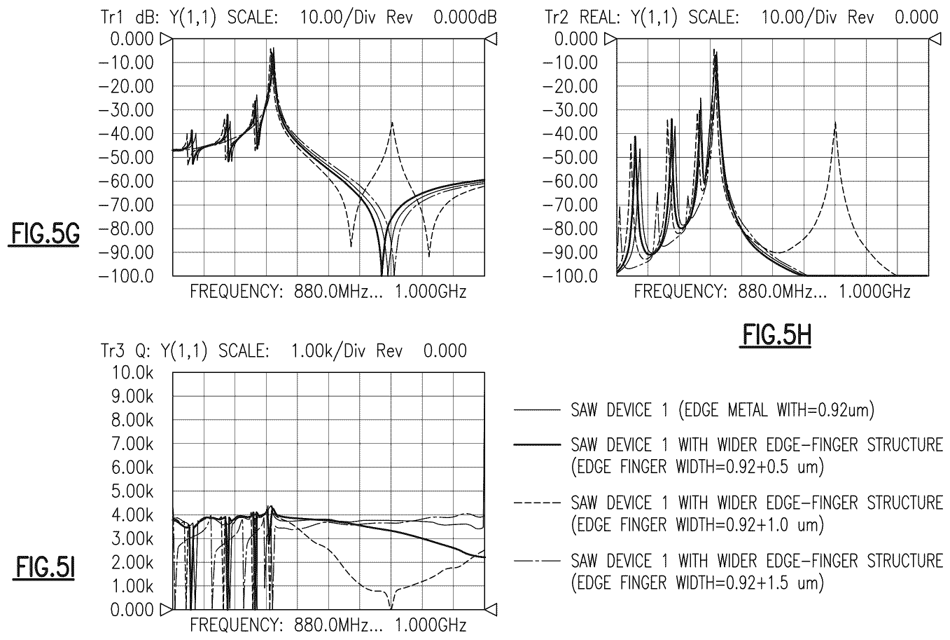

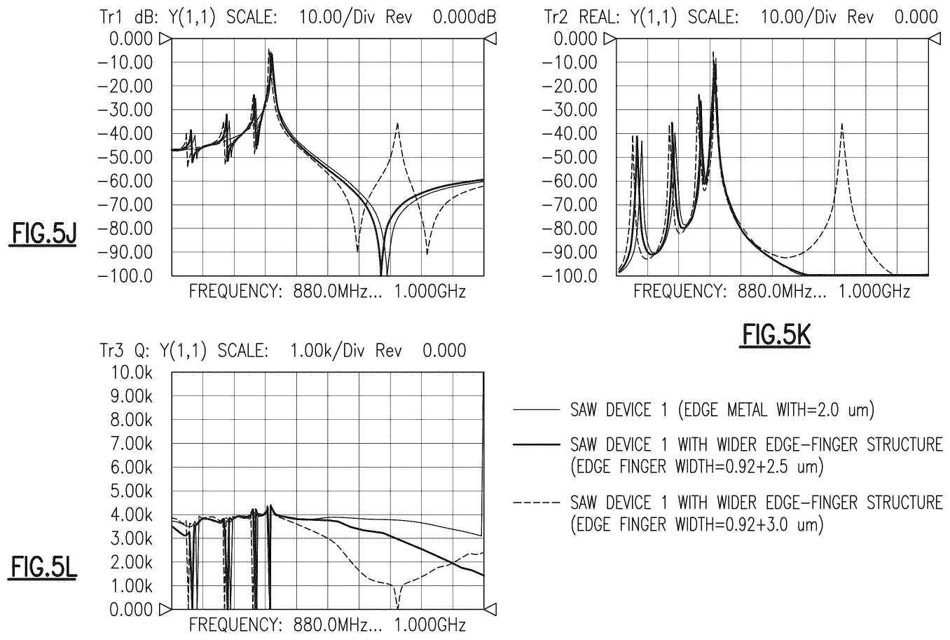

FIGS. 5A-5C are graphs showing simulation results of the performance of the SAW device 1 with different gaps g (at g1=1 μm, 2 μm, and 4 μm) between the IDT electrode 14 and the slit 15a, 15b. In the simulations, a 1000 nm silicon substrate is used as the support substrate 10, a 1000 nm thick lithium tantalate layer is used as the piezoelectric layer 12, a 1000 nm thick silicon dioxide (SiO2) layer is used as the functional layer 13a, a 1000 nm polycrystalline silicon layer is used as the trap-rich layer 13b, and the depth d of the slits 15a, 15b is set to 3000 nm. In the simulations, the wavelength L is set to 4 μm. The simulation results indicate that when the gap g1 is greater, the unwanted spikes that are formed at a lower frequency range (e.g., below the resonant frequency) can be smaller. At g1=4 μm or 1 L, the spikes can be suppressed significantly.

FIGS. 5D-5F are graphs showing simulation results of the performance of a conventional SAW device having a grating metal reflector, the SAW device 1, and the SAW device 1 with the wider edge-finger structure. In the simulations, the wavelength L is set to 4 μm and the duty factor is set to 0.46. Also, in the simulations, the fingers of the SAW devices are set to 0.92 μm, and a spacing between adjacent fingers is set to 1.08 μm. For the SAW device 1 with the wider edge-finger structure, the widths w20, w22 of the first and second edge fingers 20, 22 are set to 2.42 μm, which is 1.5 μm greater than the other fingers or about 2.6 times the width of the other fingers. The simulation results indicate that the wider edge-finger structure can provide longitudinal mode suppression, further improving the quality factor Q.

FIGS. 5G-5L are graphs showing simulation results of the performance of the SAW device 1, and the SAW device 1 with the wider edge-finger structure. In these simulations, the widths w20, w22 of the first and second edge fingers 20, 22 are swept from 0.92 μm to 3.92 μm with an increment of 0.5 μm. FIGS. 5G-5L indicate that, in the configurations used in the simulations, when the widths w20, w22 are set to 2.42 μm, the longitudinal mode is suppressed over other values for the widths w20, w22.

The slits disclosed herein can be combined with a grating reflector. A reflector that includes a slit and a grating reflector can be referred to as a hybrid reflector. In some applications, the spike(s) that is formed at a lower frequency shown in some of the simulation results herein can be undesirable or unwanted. In such applications, the hybrid reflector structure can be beneficial.

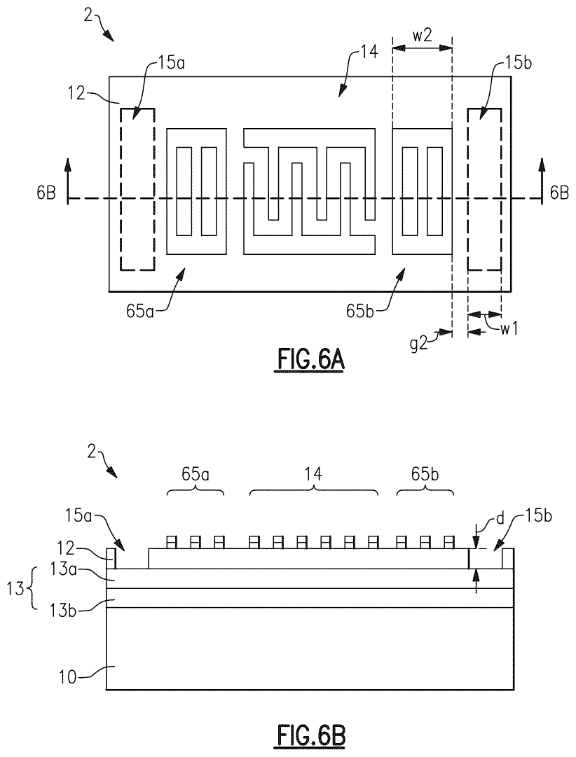

FIG. 6A is a schematic top plan view of a SAW device 2 according to an embodiment. FIG. 6B is a schematic cross-sectional side view of the SAW device 2 of FIG. 6A. Unless otherwise noted, the components shown in FIGS. 6A and 6B may be structurally and/or functionally the same as or generally similar to like components disclosed herein. Unlike the SAW device 1 disclosed herein, the SAW device 2 also includes a pair of grating reflectors 65a, 65b.

The SAW device 2 is an example of a multilayer piezoelectric substrate surface acoustic wave (MPS-SAW) device. The SAW device 2 can include a multi-layer piezoelectric substrate (MPS) that includes a support substrate 10, a piezoelectric layer 12, and an intermediate structure 13 between the support substrate 10 and the piezoelectric layer 12. The support substrate 10 and the intermediate structure 13 can be part of a support structure of the MPS. The SAW device 2 can include an interdigital transducer (IDT) electrode 14 in electrical communication with the piezoelectric layer 12, and a reflector including a pair of slits 15a, 15b and the grating reflectors 65a, 65b positioned in a wave propagation direction of the IDT electrode 14.

The slit 15a, 15b and the reflector 65a, 65b can be spaced apart by a gap g2. The gap g2 can be in a range between, for example, 0 and 10 μm, 1 μm and 10 μm, 2 μm and 10 μm, 1 μm and 5 μm, or 3 μm and 4 μm. In some embodiments, the gap g2 can be in a range between 0 and 2 L, 0.5 L and 2 L, 1 L and 2 L, or 0.5 L and 1.5 L. The grating reflectors 65a, 65b can include any suitable metal. For example, the grating reflector 65a, 65b can include the same material as the IDT electrode 14. In some embodiments, the pitches of the grating reflectors 65a, 65b can be modulated.

In a SAW device that uses only a grating reflector as its reflector, the number of fingers or a width of the reflector in the wave propagation direction may be greater than 10% greater than 25%, or greater than 50% of the number of fingers or a width of the IDT electrode of the SAW device. In the SAW device 2, a width w2 of the grating reflectors 65a, 65b can be less than 10%, less than 8%, less than 5%, or less than 3% of a width of the IDT electrode 14. For example, the width w2 of the grating reflector 65a, 65b can be in a range of 2 μm and 20 μm, 2 μm and 10 μm, or 2 μm and 5 μm. Therefore, the hybrid reflector structure that includes the grating reflector 65a, 65b and the slits 15a, 15b can significantly reduce the size of the SAW device 2 as compared to a similar SAW device that only includes a grating metal reflector, without significantly degrading the performance.

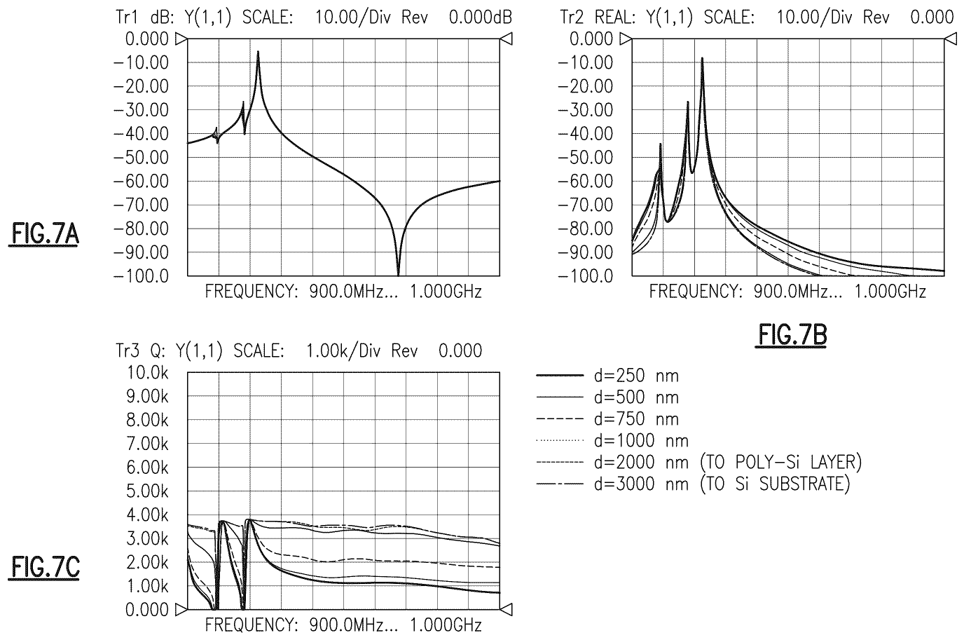

FIGS. 7A-7C are graphs showing simulation results of the performance of the SAW device 2 with different depths d (at d =250 nm, 500 nm, 750 nm, 1000 nm, 2000 nm, and 3000 nm) of the slits 15a, 15b. In the simulations, a 1000 nm silicon substrate is used as the support substrate 10, a 1000 nm thick lithium tantalate layer is used as the piezoelectric layer 12, a 1000 nm thick silicon dioxide (SiO2) layer is used as the functional layer 13a, and a 1000 nm polycrystalline silicon layer is used as the trap-rich layer 13b. The grating reflectors 65a, 65b used in the simulations of FIGS. 7A-7C each includes 5 fingers. The simulation results of FIGS. 7A-7C indicate that the slits 15a, 15b can provide sufficient reflector function when the depth d is greater than 1000 nm, greater than 2000 nm or greater than 3000 nm, and can provide more effective reflector function when the depth is greater.

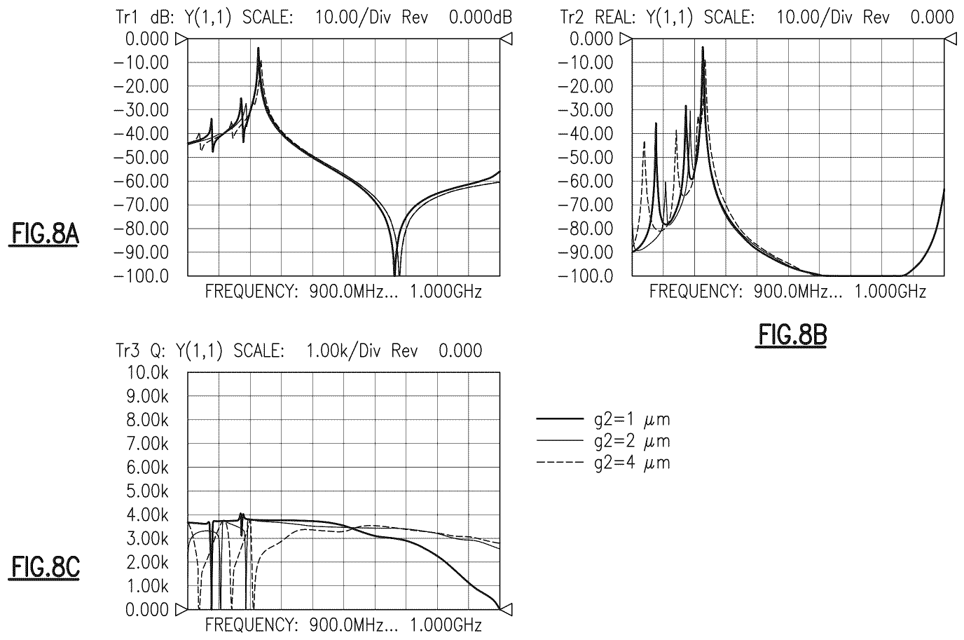

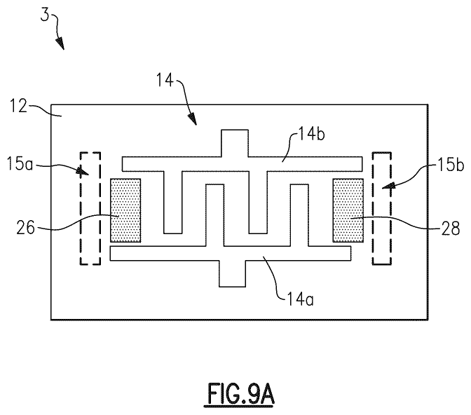

FIGS. 8A-8C are graphs showing simulation results of the performance of the SAW device 2 with different gaps g2 (at g2=1 μm, 2 μm, and 4 μm) between the IDT electrode 14 and the slit 15a, 15b. In the simulations, a 1000 nm silicon substrate is used as the support substrate 10, a 1000 nm thick lithium tantalate layer is used as the piezoelectric layer 12, a 1000 nm thick silicon dioxide (SiO2) layer is used as the functional layer 13a, a 1000 nm polycrystalline silicon layer is used as the trap-rich layer 13b, and the depth d of the slits 15a, 15b is set to 3000 nm. In the simulations, the wavelength L is set to 4 μm, and grating reflectors 65a, 65b each includes 5 fingers. The simulation results indicate that when the gap g2 is greater, the unwanted spikes that are formed at a lower frequency range can be smaller. At g1=4 μm or 1 L, the spikes can be suppressed significantly.

Comparing the results of FIGS. 4A-5C and the results of FIGS. 7A-8C, the hybrid reflector structure that includes the grating reflector 65a, 65b and the slits 15a, 15b can mitigate formation of the spikes at a lower frequency range.

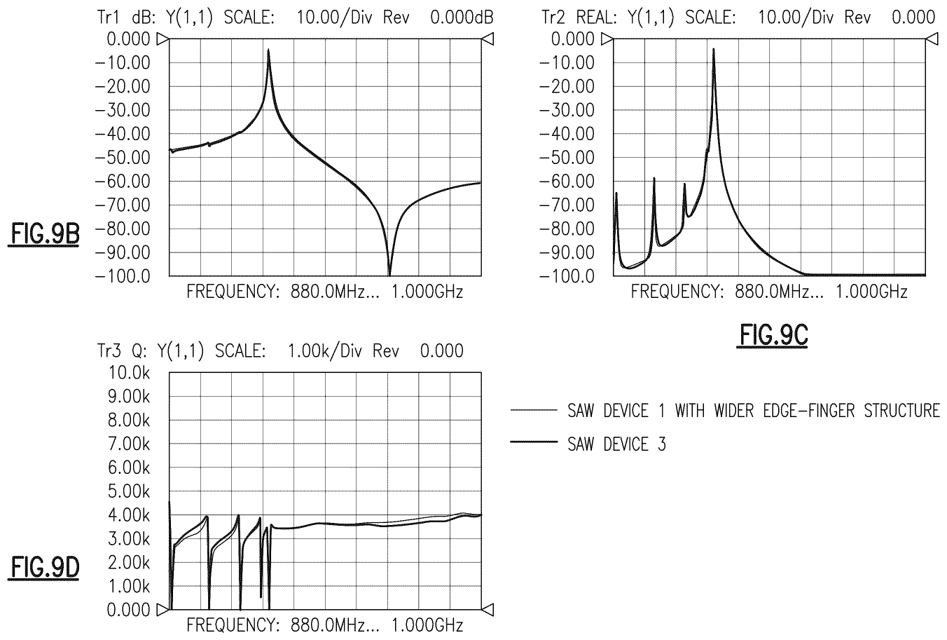

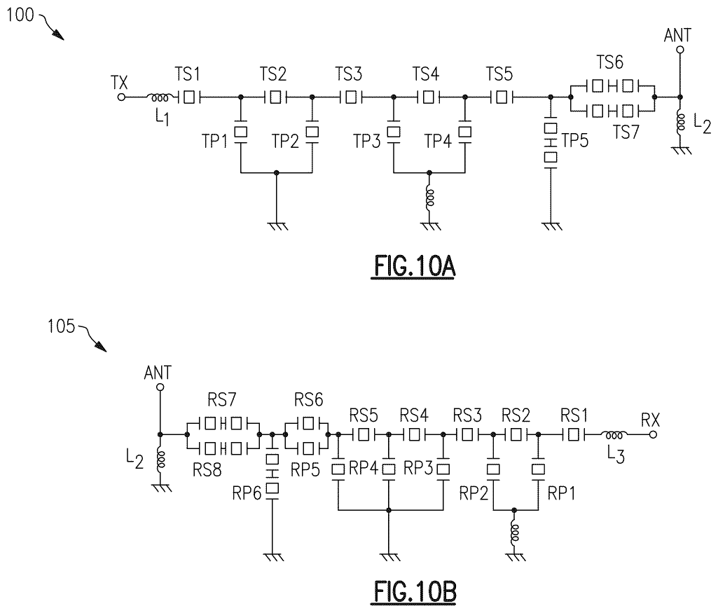

FIG. 9A is a schematic top plan view of a surface acoustic wave (SAW) device 3 according to an embodiment. Unless otherwise noted, the components shown in FIG. 9A may be structurally and/or functionally the same as or generally similar to like components disclosed herein. The SAW device 3 can be generally similar to the SAW device 1 shown in FIGS. 1A and 1B. However, in the SAW device 3, instead of the first edge finger 20 and the second edge finger 22 of SAW device 1, a first floating element 26 and a second floating element 28 can function as a longitudinal mode suppression structure. A gap between the first floating element 26 and the slit 15a and a gap between the second floating element 28 and the slit 15b can be the same as or generally similar to the gap g1 disclosed herein.

The first floating element 26 and the second floating element 28 can be separated from the first electrode element 14a and the second electrode element 14b. In some embodiments, the first floating element 26 and the second floating element 28 can include an electrically conductive material such as metal. For example, the first floating element 26 and the second floating element 28 can include a material of the IDT electrode 14. The first floating element 26 can be positioned between the slit 15a and the IDT electrode 14 in the wave propagation direction, and second floating element 28 can be positioned between the slit 15b and the IDT electrode 14 in the wave propagation direction.

FIGS. 9B-9D are graphs showing simulation results of the performance of the SAW device 1 with the wider edge-finger structure and the SAW device 3. In the simulations, the wavelength L is set to 4 μm and the duty factor is set to 0.46. Also, in the simulations, the fingers of the SAW devices are set to 0.92 μm, and a spacing between adjacent fingers is set to 1.08 μm. For the SAW device 1 with the wider edge-finger structure, the widths w20, w22 of the first and second edge fingers 20, 22 are set to 2.42 μm. For the SAW device 3, widths of the first and second floating elements are set to 2.42 μm. The simulation results indicate that the floating elements can suppress the longitudinal mode as with the wider edge-finger structure.

The widths of the first floating element 26 and/or the second floating element 28 can be in a range of, for example, 1.5 to 3 times the width of the fingers located between the first floating element 26 and the second floating element 28. The widths of the first floating element 26 and/or the second floating element 28 can be in a range of, for example, 1.275 μm to 3 μm, 2 μm to 3 μm, or 2.2 μm to 2.7 μm. The first floating element 26 and/or the second floating element 28 may be implemented in any SAW devices disclosed herein. For example, first floating element 26 may be positioned between the grating reflector 65a and the slit 15a, and the second floating element 28 may be provided between the grating reflector 65b and the slit 15b in the SAW device 2 shown in FIGS. 6A and 6B.

An acoustic wave device (e.g., a SAW device) including any suitable combination of features disclosed herein can be included in a filter arranged to filter a radio frequency signal in a fifth generation (5G) New Radio (NR) operating band within Frequency Range 1 (FR1). A filter arranged to filter a radio frequency signal in a 5G NR operating band can include one or more conductive structures disclosed herein. FR1 can be from 410 MHz to 7.125 GHz, for example, as specified in a current 5G NR specification. One or more acoustic wave devices in accordance with any suitable principles and advantages disclosed herein can be included in a filter arranged to filter a radio frequency signal in a 4G LTE operating band and/or in a filter having a passband that includes a 4G LTE operating band and a 5G NR operating band.

FIG. 10A is a schematic diagram of an example transmit filter 100 that includes surface acoustic wave devices according to an embodiment. The transmit filter 100 can be a band-pass filter. The illustrated transmit filter 100 is arranged to filter a radio frequency signal received at a transmit port TX and provide a filtered output signal to an antenna port ANT. Some or all of the SAW resonators TS1 to TS7 and/or TP1 to TP5 can be SAW devices in accordance with any suitable principles and advantages disclosed herein. For instance, one or more of the SAW resonators of the transmit filter 100 can be coupled by way of a conductive structure disclosed herein. Any suitable number of series SAW resonators and shunt SAW resonators can be included in a transmit filter 100.

FIG. 10B is a schematic diagram of a receive filter 105 that includes surface acoustic wave devices according to an embodiment. The receive filter 105 can be a band-pass filter. The illustrated receive filter 105 is arranged to filter a radio frequency signal received at an antenna port ANT and provide a filtered output signal to a receive port RX. Some or all of the SAW resonators RS1 to RS8 and/or RP1 to RP6 can be SAW resonators in accordance with any suitable principles and advantages disclosed herein. Any suitable number of series SAW resonators and shunt SAW resonators can be included in a receive filter 105.

Although FIGS. 10A and 10B illustrate example ladder filter topologies, any suitable filter topology can include a SAW device in accordance with any suitable principles and advantages disclosed herein. Example filter topologies include ladder topology, a lattice topology, a hybrid ladder and lattice topology, a multi-mode SAW filter, a multi-mode SAW filter combined with one or more other SAW resonators, and the like.

FIG. 11 is a schematic diagram of a radio frequency module 175 that includes a surface acoustic wave component 176. The illustrated radio frequency module 175 includes the SAW component 176 and other circuitry 177. The SAW component 176 can include one or more SAW resonators with any suitable combination of features of the SAW resonators disclosed herein. The SAW component 176 can include a SAW die that includes SAW resonators.

The SAW component 176 shown in FIG. 11 includes a filter 178 and terminals 179A and 179B. The filter 178 includes SAW resonators. One or more of the SAW resonators can be implemented in accordance with any suitable principles and advantages of any surface acoustic wave device disclosed herein. The terminals 179A and 179B can serve, for example, as an input contact and an output contact. The SAW component 176 and the other circuitry 177 are on a common packaging substrate 180 in FIG. 11. The package substrate 180 can be a laminate substrate. The terminals 179A and 179B can be electrically connected to contacts 181A and 181B, respectively, on the packaging substrate 180 by way of electrical connectors 182A and 182B, respectively. The electrical connectors 182A and 182B can be bumps or wire bonds, for example. The other circuitry 177 can include any suitable additional circuitry. For example, the other circuitry can include one or more one or more power amplifiers, one or more radio frequency switches, one or more additional filters, one or more low noise amplifiers, the like, or any suitable combination thereof. The radio frequency module 175 can include one or more packaging structures to, for example, provide protection and/or facilitate easier handling of the radio frequency module 175. Such a packaging structure can include an overmold structure formed over the packaging substrate 180. The overmold structure can encapsulate some or all of the components of the radio frequency module 175.

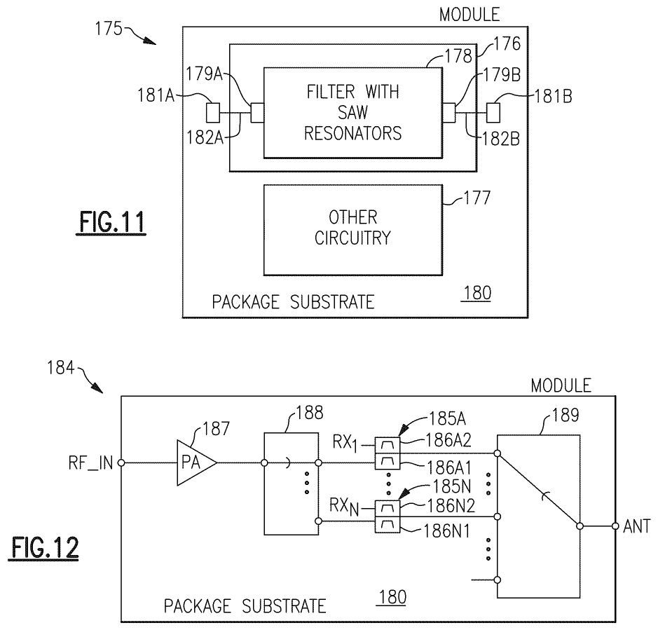

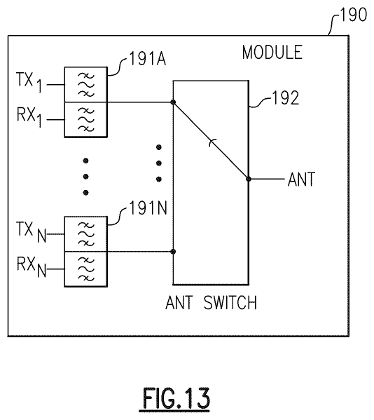

FIG. 12 is a schematic diagram of a radio frequency module 184 that includes a surface acoustic wave resonator according to an embodiment. As illustrated, the radio frequency module 184 includes duplexers 185A to 185N that include respective transmit filters 186A1 to 186N1 and respective receive filters 186A2 to 186N2, a power amplifier 187, a select switch 188, and an antenna switch 189. In some instances, the module 184 can include one or more low noise amplifiers configured to receive a signal from one or more receive filters of the receive filters 186A2 to 186N2. The radio frequency module 184 can include a package that encloses the illustrated elements. The illustrated elements can be disposed on a common packaging substrate 180. The packaging substrate can be a laminate substrate, for example.

The duplexers 185A to 185N can each include two acoustic wave filters coupled to a common node. The two acoustic wave filters can be a transmit filter and a receive filter. As illustrated, the transmit filter and the receive filter can each be band-pass filters arranged to filter a radio frequency signal. One or more of the transmit filters 186A1 to 186N1 can include one or more SAW resonators in accordance with any suitable principles and advantages disclosed herein. Similarly, one or more of the receive filters 186A2 to 186N2 can include one or more SAW resonators in accordance with any suitable principles and advantages disclosed herein. Although FIG. 12 illustrates duplexers, any suitable principles and advantages disclosed herein can be implemented in other multiplexers (e.g., quadplexers, hexaplexers, octoplexers, etc.) and/or in switch-plexers and/or to standalone filters.

The power amplifier 187 can amplify a radio frequency signal. The illustrated switch 188 is a multi-throw radio frequency switch. The switch 188 can electrically couple an output of the power amplifier 187 to a selected transmit filter of the transmit filters 186A1 to 186N1. In some instances, the switch 188 can electrically connect the output of the power amplifier 187 to more than one of the transmit filters 186A1 to 186N1. The antenna switch 189 can selectively couple a signal from one or more of the duplexers 185A to 185N to an antenna port ANT. The duplexers 185A to 185N can be associated with different frequency bands and/or different modes of operation (e.g., different power modes, different signaling modes, etc.).

FIG. 13 is a schematic block diagram of a module 190 that includes duplexers 191A to 191N and an antenna switch 192. One or more filters of the duplexers 191A to 191N can include any suitable number of surface acoustic wave resonators in accordance with any suitable principles and advantages discussed herein. Any suitable number of duplexers 191A to 191N can be implemented. The antenna switch 192 can have a number of throws corresponding to the number of duplexers 191A to 191N. The antenna switch 192 can electrically couple a selected duplexer to an antenna port of the module 190.

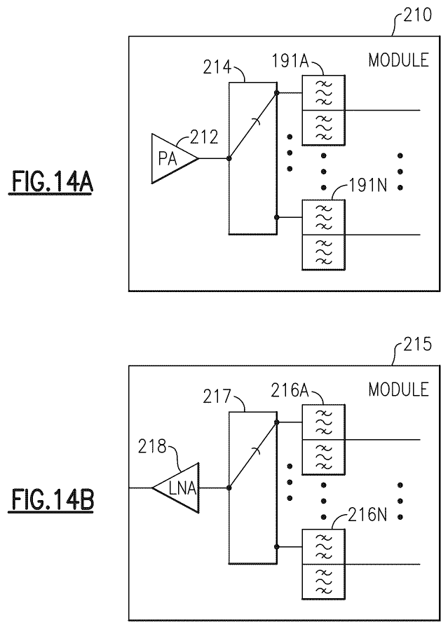

FIG. 14A is a schematic block diagram of a module 210 that includes a power amplifier 212, a radio frequency switch 214, and duplexers 191A to 191N in accordance with one or more embodiments. The power amplifier 212 can amplify a radio frequency signal. The radio frequency switch 214 can be a multi-throw radio frequency switch. The radio frequency switch 214 can electrically couple an output of the power amplifier 212 to a selected transmit filter of the duplexers 191A to 191N. One or more filters of the duplexers 191A to 191N can include any suitable number of surface acoustic wave resonators in accordance with any suitable principles and advantages discussed herein. Any suitable number of duplexers 191A to 191N can be implemented.

FIG. 14B is a schematic block diagram of a module 215 that includes filters 216A to 216N, a radio frequency switch 217, and a low noise amplifier 218 according to an embodiment. One or more filters of the filters 216A to 216N can include any suitable number of acoustic wave resonators in accordance with any suitable principles and advantages disclosed herein. Any suitable number of filters 216A to 216N can be implemented. The illustrated filters 216A to 216N are receive filters. In some embodiments, one or more of the filters 216A to 216N can be included in a multiplexer that also includes a transmit filter. The radio frequency switch 217 can be a multi-throw radio frequency switch. The radio frequency switch 217 can electrically couple an output of a selected filter of filters 216A to 216N to the low noise amplifier 218. In some embodiments, a plurality of low noise amplifiers can be implemented. The module 215 can include diversity receive features in certain applications.

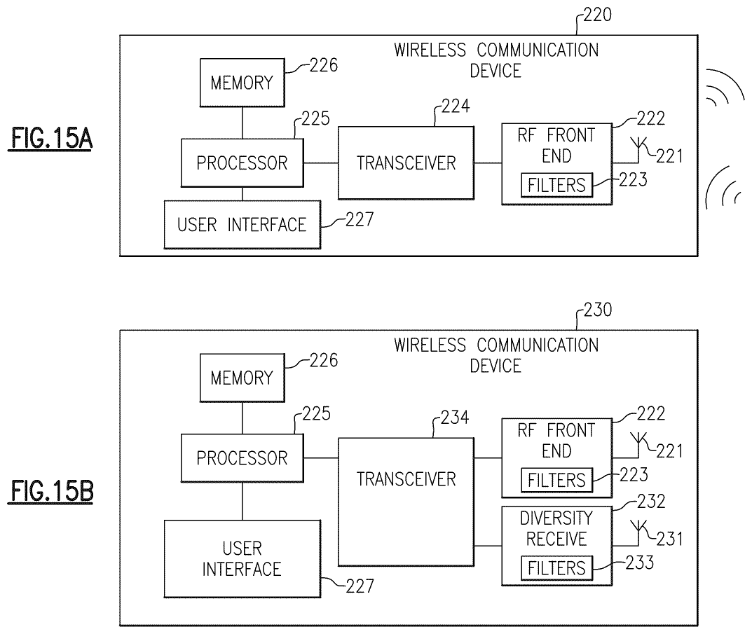

FIG. 15A is a schematic diagram of a wireless communication device 220 that includes filters 223 in a radio frequency front end 222 according to an embodiment. The filters 223 can include one or more SAW resonators in accordance with any suitable principles and advantages discussed herein. The wireless communication device 220 can be any suitable wireless communication device. For instance, a wireless communication device 220 can be a mobile phone, such as a smart phone. As illustrated, the wireless communication device 220 includes an antenna 221, an RF front end 222, a transceiver 224, a processor 225, a memory 226, and a user interface 227. The antenna 221 can transmit/receive RF signals provided by the RF front end 222. Such RF signals can include carrier aggregation signals. Although not illustrated, the wireless communication device 220 can include a microphone and a speaker in certain applications.

The RF front end 222 can include one or more power amplifiers, one or more low noise amplifiers, one or more RF switches, one or more receive filters, one or more transmit filters, one or more duplex filters, one or more multiplexers, one or more frequency multiplexing circuits, the like, or any suitable combination thereof. The RF front end 222 can transmit and receive RF signals associated with any suitable communication standards. The filters 223 can include SAW resonators of a SAW component that includes any suitable combination of features discussed with reference to any embodiments discussed above.

The transceiver 224 can provide RF signals to the RF front end 222 for amplification and/or other processing. The transceiver 224 can also process an RF signal provided by a low noise amplifier of the RF front end 222. The transceiver 224 is in communication with the processor 225. The processor 225 can be a baseband processor. The processor 225 can provide any suitable base band processing functions for the wireless communication device 220. The memory 226 can be accessed by the processor 225. The memory 226 can store any suitable data for the wireless communication device 220. The user interface 227 can be any suitable user interface, such as a display with touch screen capabilities.

FIG. 15B is a schematic diagram of a wireless communication device 230 that includes filters 223 in a radio frequency front end 222 and a second filter 233 in a diversity receive module 232. The wireless communication device 230 is like the wireless communication device 220 of FIG. 15A, except that the wireless communication device 230 also includes diversity receive features. As illustrated in FIG. 15B, the wireless communication device 230 includes a diversity antenna 231, a diversity module 232 configured to process signals received by the diversity antenna 231 and including filters 233, and a transceiver 234 in communication with both the radio frequency front end 222 and the diversity receive module 232. The filters 233 can include one or more SAW resonators that include any suitable combination of features discussed with reference to any embodiments discussed above.

Any of the embodiments described above can be implemented in association with mobile devices such as cellular handsets. The principles and advantages of the embodiments can be used for any systems or apparatus, such as any uplink wireless communication device, that could benefit from any of the embodiments described herein. The teachings herein are applicable to a variety of systems. Although this disclosure includes some example embodiments, the teachings described herein can be applied to a variety of structures. Any of the principles and advantages discussed herein can be implemented in association with RF circuits configured to process signals in a frequency range from about 30 kHz to 300 GHz, such as in a frequency range from about 450 MHz to 8.5 GHz. Acoustic wave resonators and/or filters disclosed herein can filter RF signals at frequencies up to and including millimeter wave frequencies.

Aspects of this disclosure can be implemented in various electronic devices. Examples of the electronic devices can include, but are not limited to, consumer electronic products, parts of the consumer electronic products such as packaged radio frequency modules and/or packaged filter components, uplink wireless communication devices, wireless communication infrastructure, electronic test equipment, etc. Examples of the electronic devices can include, but are not limited to, a mobile phone such as a smart phone, a wearable computing device such as a smart watch or an ear piece, a telephone, a television, a computer monitor, a computer, a modem, a hand-held computer, a laptop computer, a tablet computer, a microwave, a refrigerator, a vehicular electronics system such as an automotive electronics system, a stereo system, a digital music player, a radio, a camera such as a digital camera, a portable memory chip, a washer, a dryer, a washer/dryer, a copier, a facsimile machine, a scanner, a multi-functional peripheral device, a wrist watch, a clock, etc. Further, the electronic devices can include unfinished products.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. As used herein, the term “approximately” intends that the modified characteristic need not be absolute, but is close enough so as to achieve the advantages of the characteristic. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

What is claimed is:

1. A surface acoustic wave device comprising:
a multi-layer piezoelectric substrate including a support substrate and a piezoelectric layer;
an interdigital transducer electrode in electrical communication with the piezoelectric layer; and
a slit positioned in a wave propagation direction of the interdigital transducer electrode, the slit having a depth extending at least partially through a thickness of the multi-layer piezoelectric substrate.

2. The surface acoustic wave device of claim 1 wherein the multi-layer piezoelectric substrate further includes an intermediate layer between the support substrate and the piezoelectric layer.

3. The surface acoustic wave device of claim 2 wherein the depth of the slit extends through an entire thickness of the piezoelectric layer.

4. The surface acoustic wave device of claim 3 wherein the depth of the slit extends through an entire thickness of the intermediate layer.

5. The surface acoustic wave device of claim 1 wherein the depth of the slit extends through an entire thickness of the piezoelectric layer and partially through a thickness of the support substrate.

6. The surface acoustic wave device of claim 1 wherein a gap between the slit and the interdigital transducer electrode is in a range between 0 and 2 L where L is a wavelength of a wave generated by the surface acoustic wave device.

7. The surface acoustic wave device of claim 6 wherein a gap between the slit and the interdigital transducer electrode is in a range between 0.75 L and 1.25 L.

8. The surface acoustic wave device of claim 1 further comprising a second slit, wherein the interdigital transducer electrode is positioned between the slit and the second slit.

9. The surface acoustic wave device of claim 1 wherein a length of the slit is greater than a length of a finger of the interdigital transducer electrode.

10. The surface acoustic wave device of claim 1 wherein the interdigital transducer electrode is positioned at or near an edge of the multi-layer piezoelectric substrate, the interdigital transducer electrode positioned between the edge and the slit such that the edge of the multi-layer piezoelectric substrate and the slit function as a pair of reflectors.

11. The surface acoustic wave device of claim 1 wherein the interdigital transducer electrode includes a plurality of fingers including a first edge finger, a second edge finger, and center fingers between the first edge finger and the second edge finger, the first edge finger is closest to the slit among the plurality of fingers and has a width greater than a width of the center fingers.

12. The surface acoustic wave device of claim 11 wherein the second edge finger has a width greater than the width of the center fingers.

13. The surface acoustic wave device of claim 11 wherein the width of the first edge finger is in a range between 1.5 to 10 times the width of the center fingers.

14. A surface acoustic wave device comprising:
a piezoelectric layer;
an interdigital transducer electrode in electrical communication with the piezoelectric layer; and
a pair of slits including a first slit and a second slit positioned in a wave propagation direction of the interdigital transducer electrode, the interdigital transducer electrode is positioned between the pair of slits, the slit having a depth extending at least partially through a thickness of the piezoelectric layer.

15. The surface acoustic wave device of claim 14 wherein the depth of the slit is at least 1 L where L is a wavelength of a wave generated by the surface acoustic wave device.

16. The surface acoustic wave device of claim 14 wherein a gap between the slit and the interdigital transducer electrode is in a range between 0.5 L and 2 L.

17. The surface acoustic wave device of claim 14 wherein the interdigital transducer electrode includes a plurality of fingers including a first edge finger, a second edge finger, and center fingers between the first edge finger and the second edge finger, the first edge finger is closest to the first slit among the plurality of fingers and has a width greater than a width of the center fingers, and the second edge finger is positioned closest to the second slit among the plurality of fingers and has a width greater than the width of the center fingers.

18. A surface acoustic wave device comprising:
a multi-layer piezoelectric substrate including a support substrate and a piezoelectric layer;
an interdigital transducer electrode in electrical communication with the piezoelectric layer; and
a slit positioned in a wave propagation direction of the interdigital transducer electrode, the slit extending at least 0.25 L into the multi-layer piezoelectric substrate, L being a wavelength of a wave generated by the surface acoustic wave device.

19. The surface acoustic wave device of claim 18 wherein the slit extends at least 1 L into the multi-layer piezoelectric substrate.

20. The surface acoustic wave device of claim 18 wherein the slit extends into the multi-layer piezoelectric substrate in a range between 0.25 L and 1.5 L.
